(19) United States
(12) Patent Application Publication
(10) Pub. No.: US 2022/0148845 A1
(43) Pub. Date: May 12, 2022

(54) Stage Movement Control Apparatus and Charged Particle Beam System

(71) Applicant: Hitachi High-Tech Corporation, Minato-ku, Tokyo (JP)

(72) Inventors: Hironori OGAWA, Tokyo (JP); Shuichi NAKAGAWA, Tokyo (JP); Masaki MIZUOCHI, Tokyo (JP); Takanori KATO, Tokyo (JP); Naruo WATANABE, Tokyo (JP); Motohiro TAKAHASHI, Tokyo (JP)

(21) Appl. No.: 17/435,869

(22) PCT Filed: Mar. 19, 2019
(86) PCT No.: PCT/JP2019/011514

§ 371 Date: Sep. 2, 2021

(51) Int. Cl. H01J 37/20; H01J 37/28; H01J 37/147

(52) U.S. Cl. CPC H01J 37/20; H01J 37/147; H01J 37/28

(57) ABSTRACT

In order to improve the accuracy of stage movement in a charged particle beam apparatus, this stage movement control apparatus is characterized by comprising: a storage device in which overshoot amount data in which the movement distance of a stage and the overshoot amount of the stage are associated is stored; a movement target position setting unit which sets the movement target position of the stage; a stage movement amount calculation unit which calculates a stage movement amount that is an amount by which the stage moves to the movement target position in future; an overshoot estimation unit which, on the basis of the calculated stage movement amount and the overshoot amount data, estimates an overshoot amount corresponding to the stage movement amount; a movement target position correction unit which sets a corrected movement target position obtained by correcting the movement target position closer than the movement target position by the calculated overshoot amount; and a stage movement control unit which moves the stage to the corrected movement target position.

### TECHNICAL FIELD

The present invention relates to a technology of a stage movement control apparatus and charged particle beam system.

### BACKGROUND ART

With miniaturization of semiconductor elements, not only manufacturing devices but also inspection and evaluation devices are required to have high accuracy corresponding to the miniaturization. Normally, a scanning electron microscope (hereinafter referred to as SEM as appropriate) is used to evaluate a pattern formed on a semiconductor wafer (hereinafter referred to as wafer) and to inspect defects in the formed wafer. In particular, a length measurement SEM is used to evaluate a shape and dimension of a pattern of a semiconductor element.

The length measurement SEM irradiates the wafer with an electron beam, and generates a secondary electron image (hereinafter referred to as SEM image) from the obtained secondary electron signal. The length measurement SEM derives the dimension or the like by discriminating the edge of the pattern from the change in brightness of the obtained SEM image. In order to observe and inspect the entire wafer, the length measurement SEM is provided with a stage capable of positioning a desired position on the wafer at the irradiation position of the beam by moving in the XY direction (horizontal plane direction). Examples of the operation of the stage include a method in which the stage is driven by a rotation motor and a ball screw, and a method in which the stage is driven by a linear motor. In some cases, a stage that performs rotational motion not only on the XY plane but also on the Z axis (vertical direction) and about the Z axis is used.

In the inspection of the wafer by the length measurement SEM, positioning of the stage is performed so that the measurement point comes to the irradiation position (immediately below the center of the column) of the electron beam by using the value of the laser interferometer (hereinafter referred to as laser value) in order to accurately observe the measurement point on the wafer set in advance. Thereafter, the SEM image is imaged, and dimension measurement and inspection are performed using the obtained SEM image. This series of operations (stage movement and imaging) is repeated for a plurality of measurement points to perform processing for one wafer. That is, the XY stage moves by repeating a step-and-repeat operation. In the length measurement SEM, since the movement time of the stage is a major element determining the throughput of the length measurement SEM, shortening of the stage movement time is strongly required.

Normally, when positioning the stage using a linear motor, it is common to perform so-called servo control, in which a difference between the movement target position and the current position is periodically fed back. When performing stage movement using servo control, an overshoot or undershoot with respect to the movement target position often occurs due to control factors, some disturbance, modeling errors, machine difference, and the like. In particular, when the stage is moved at high speed to shorten the positioning time, the overshoot amount of the stage tends to increase.

In the length measurement SEM, when the position deviation remains after positioning of the stage, the irradiation position can be shifted in the XY direction (beam shift) by deflecting the electron beam. This beam shift enables the electron beam to be irradiated to a desired position on the wafer, and the measurement point to be accurately observed. At the same time, the positioning time can be shortened by canceling, by the beam shift, the overshoot occurring at the time of positioning of the stage.

However, in order to perform beam shift, it is necessary to control the beam trajectory by various electrical and magnetic lenses. In some cases, distortion occurs in the plane of the SEM image obtained by the beam shift. The trajectory of the electron beam sometimes changes due to performing of beam shift, thereby sometimes causing the incident angle with respect to the wafer to deviate from a right angle (beam tilt). This beam tilt causes deterioration in inspection accuracy due to a decrease in the secondary electron amount to be obtained, particularly in observation of a deep hole structure having a large aspect ratio (dimension ratio in the plane direction and the depth direction).

Thus, in order to avoid deterioration in inspection accuracy due to distortion of the SEM image and a decrease in the secondary electron amount, it is necessary to reduce the beam shift amount by accurately positioning the measurement point at the beam irradiation position. In this case, since the cancelable amount of the position deviation due to the conventionally performed beam shift becomes small, it is necessary to reduce the deviation of the stage relative to the movement target position, and the positioning time increases. A deflectable range is normally defined for the beam shift due to electrical, mechanical, and other constraints. If the position deviation of the stage exceeds this deflectable range, there is a possibility that the measurement position cannot be accurately imaged in the SEM image.

When a plurality of measurement points are close to one another on the wafer, the field of view is moved by using the beam shift, and the plurality of points can be imaged without performing stage movement. However, even in this case, if the beam shift amount used for correcting the position deviation of the stage is large, the beam shift amount that can be used for the field of view movement is compressed. For this reason, the range in which a plurality of points can be imaged after one stage movement is narrowed, thereby resulting in a decrease in throughput. That is, the beam shift is used not only for the purpose of the original field of view movement but also for the position correction of the stage, and it is not efficient.

For example, PTL 1 is disclosed as a prior art that achieves high speed and high accuracy by interlocking beam shift and stage control. PTL 1 discloses a charged particle beam device, and an imaging method of the same in which “a charged particle beam device, comprising: a column equipped with an electron gun for generating a charged particle beam, and a deflector capable of deflecting a charged particle beam generated from the electron gun to a desired position; a sample chamber in which a stage configured to be moveable in which a sample irradiated with a charged particle beam generated from an electron gun is placed is arranged inside; a measure capable of measuring a position of a stage in a sample chamber; a column control unit controlling a deflection amount of a deflector of a column; and a position control unit controlling a position of a stage of a sample chamber, wherein the a charged particle beam device images a sample by irradiating a charged particle beam, the a charged particle beam device, comprising: a deviation processing unit that calculates a deviation value from a target position of a sample irradiated with a charged particle beam based on information on a state of a stage measured by a length measure; a determination unit that compares determination reference information including position information and speed information of a stage with current position information and speed information of a stage, and judges whether or not it is possible for position deviation of a stage to remain in a deflectable region of a charged particle beam for a period of time of equal to or greater than at least imaging time of a sample, and hence judges whether or not it is possible to image a sample of a state of a stage during an imaging time of a sample; and a deflection control unit commanding a deflector adjusting a deflection amount of a charged particle beam based on a deviation value calculated by the deviation processing unit, wherein a charged particle beam is irradiated to perform imaging of a sample” (see claim 1).

### CITATION LIST

### Patent Literature

PTL 1: JP 4927506 A

### SUMMARY OF INVENTION

### Technical Problem

According to the technology disclosed in PTL 1, it is possible to increase the speed while securing the image accuracy by the beam shift after stage movement, but it is necessary to further improve the overshoot amount accompanying the stage movement.

The present invention has been made in view of such a background, and an object of the present invention is to improve accuracy of stage movement in a charged particle beam device.

### Solution to Problem

In order to solve the above problem, the present invention has a storage unit that stores overshoot amount data in which a movement distance of a stage in a charged particle beam device and an overshoot amount of the stage are associated; a movement target position setting unit that sets a movement target position of the stage; a stage movement amount calculation unit that calculates a stage movement amount, which is an amount by which the stage moves in future toward the movement target position; an overshoot estimation unit that estimates the overshoot amount corresponding to the stage movement amount based on the stage movement amount having been calculated and the overshoot amount data; a movement target position correction unit that sets a correction movement target position in which the movement target position is corrected from the movement target position to a near side by the overshoot amount having been calculated; and a stage movement control unit that moves the stage with respect to the correction movement target position.

Other solutions will be described as appropriate in the embodiments.

### Advantageous Effects of Invention

According to the present invention, it is possible to improve accuracy of stage movement in a charged particle beam device.

### BRIEF DESCRIPTION OF DRAWINGS

FIG. 1 is a view illustrating a configuration of a charged particle beam system according to a present embodiment.

FIG. 2 is a functional block diagram of a control apparatus according to the present embodiment.

FIG. 3 is a flowchart presenting measurement processing of the wafer executed in the present embodiment.

FIG. 4A is an explanatory view (part 1) of a stage stabilization range in the present embodiment.

FIG. 4B is an explanatory view (part 2) of the stage stabilization range in the present embodiment.

FIG. 5 is an explanatory view (part 3) of the stage stabilization range in the present embodiment.

FIG. 6 is a view illustrating a calculation method of an estimated overshoot amount in the present embodiment.

FIG. 7 is a view illustrating conventional movement control of the stage.

FIG. 8 is a view illustrating movement control of the stage performed in the present embodiment.

FIG. 9 is a schematic view illustrating a measurement order in a case of performing imaging of a plurality of points by one stage movement.

FIG. 10 is a schematic view illustrating a measurement order in a case of performing imaging of one point for one stage movement.

FIG. 11 is a view illustrating a variation of overshoot amount data in the present embodiment.

FIG. 12 is an example of a table for setting a permissible beam shift amount in the present embodiment.

FIG. 13A is a view (part 1) illustrating a setting map of the permissible beam shift amount in an auto mode.

FIG. 13B is a view (part 2) illustrating a setting map of the permissible beam shift amount in the auto mode.

FIG. 14 is an example of a table for displaying a reference image with respect to the permissible beam shift amount in the present embodiment.

FIG. 15 is a view explaining a decision method of the permissible beam shift amount in the present embodiment.

### DESCRIPTION OF EMBODIMENTS

Next, an embodiment for carrying out the present invention (referred to as an “embodiment”) will be described in detail with reference to the drawings as appropriate. The present embodiment is to measure a semiconductor wafer (wafer), and the structure of the wafer to be measured shall be known in advance by design data or the like. The coordinate of a measurement point shall be determined in advance by a recipe (recipe information) based on the design data. Here, the measurement indicates measurement of the configuration on the wafer by a length measurement SEM, and the measurement point means a point at which measurement is performed on the wafer.

[Charged Particle Beam System G]

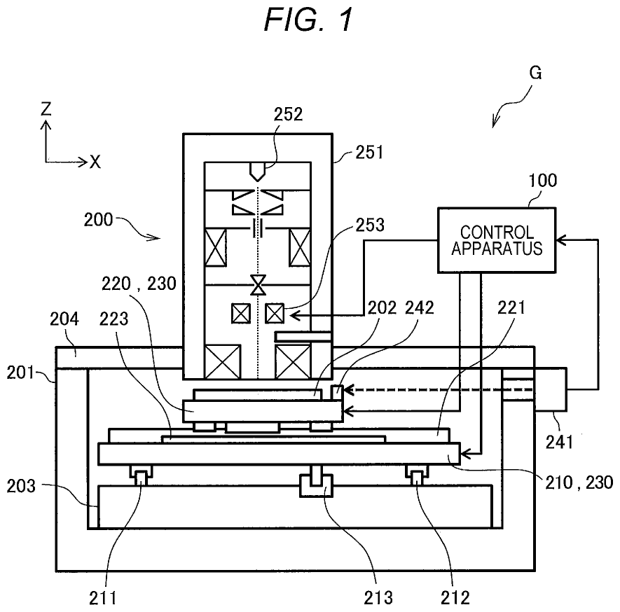

FIG. 1 is a view illustrating the configuration of a charged particle beam system G according to the present embodiment.

The charged particle beam system G has a charged particle beam device 200, which is a length measurement SEM, and a control apparatus (stage control apparatus) 100 that controls the charged particle beam device 200. FIG. 1 describes the configuration of the charged particle beam device 200, and the configuration of a control apparatus 100 will be described later. FIG. 1 illustrates a schematic cross-sectional view of the charged particle beam device 200.

In the charged particle beam device 200, a Y stage (stage) 210 is arranged on a base 203 fixed in a sample chamber 201. The Y stage 210 can freely move in the Y direction (depth direction in the drawing) via two Y linear guides 211 and 212. A Y linear motor (drive unit) 213 is arranged between the base 203 and the Y stage 210 so as to generate thrust relatively in the Y direction. On the Y stage 210, an X stage (stage) 220 that can freely move in the X direction via two X linear guides 221 (one is not illustrated) is arranged. The X linear motor (drive unit) 223 is arranged between the Y stage 210 and the X stage 220 so as to generate thrust in the X direction. This enables the X stage 220 to freely move in the XY direction with respect to the base 203 and the sample chamber 201. Hereinafter, the Y stage 210 and the X stage 220 are collectively referred to as a stage 230 as appropriate.

A wafer 202 as a sample is placed on the X stage 220. A wafer retention mechanism (not illustrated) including a retention force such as a mechanical restraint force or an electrostatic force is used for arranging the wafer 202. A top plate 204 and a column 251 are placed in the sample chamber 201. The column 251 includes an electron optical system for generating a secondary electron image by an electron beam. The electron optical system includes an electron gun 252 that generates an electron beam (charged particle beam) and a deflector 253 that can deflect the electron beam generated from the electron gun 252 to a desired position.

The X stage 220 is provided with an X mirror (position detection unit) 242. On the side surface of the sample chamber 201, an X laser interferometer (position detection unit) 241 is placed. The X laser interferometer 241 irradiates the X mirror 242 with a laser light (broken line arrow in FIG. 1), and measures the relative displacement amount (hereinafter referred to as X stage position) of the sample chamber 201 and the X stage 220 in the X direction using the reflected light. Here, the X mirror 242 has a mirror surface on the YZ plane and a rod-like shape that is long in the Y direction. Since the X mirror 242 has such a shape, the laser light can be reflected even when the Y stage 210 and the X stage 220 move in the Y direction. Similarly, in the Y direction, the relative displacement amount (hereinafter referred to as Y stage position) of the sample chamber 201 and the X stage 220 in the Y direction can be measured by a Y laser interferometer (not illustrated) and a Y mirror (not illustrated). In the present embodiment, the X stage position and the Y stage position are collectively referred to as a stage position.

Although the present embodiment assumes an example in which a linear guide is used as the drive mechanism of the stage 230, another drive mechanism (e.g., fluid bearing, magnetic bearing, or the like) can be used. Although a linear motor is used as the drive mechanism, an actuator that can be used in a vacuum such as a ball screw and a piezoelectric actuator can also be used. In the present embodiment, a laser interferometer is used for position detection of the stage 230, but another position detection method such as a linear scale, a two-dimensional scale, and a capacitance sensor may be used.

Although a length measurement SEM is assumed as the charged particle beam device 200 in the present embodiment, another charged particle beam device 200 such as a review SEM may be applied. However, in the present embodiment, as described above, it is premised that information on a portion to be imaged in advance by design data or the like is available.

[Control Apparatus 100]

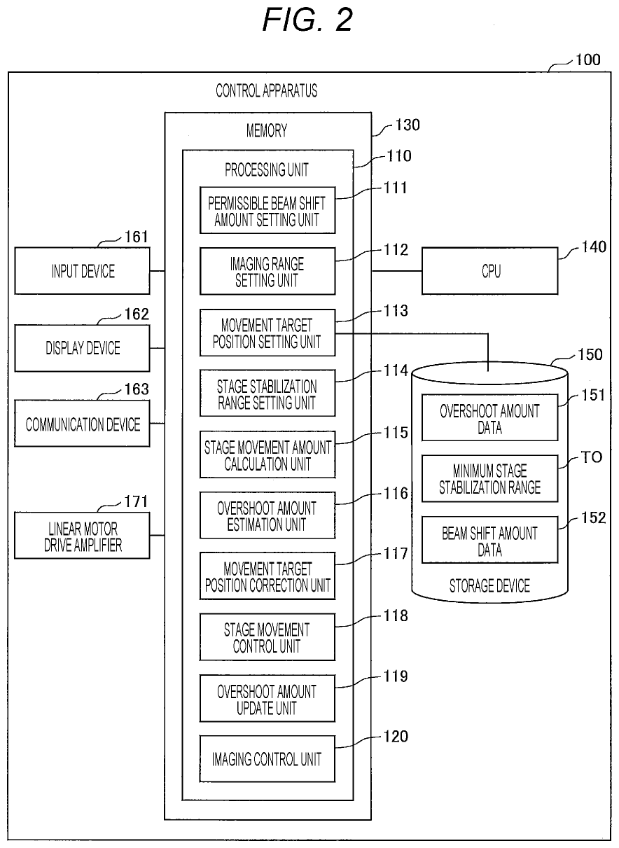

FIG. 2 is a functional block diagram of the control apparatus 100 according to the present embodiment. FIG. 1 is referred to as appropriate.

As illustrated in FIG. 2, the control apparatus 100 has a linear motor drive amplifier 171 and the like. The control apparatus 100 drives the stage 230 in the XY direction by controlling the drive current of the linear motors (Y linear motor 213 and X linear motor 223) of the charged particle beam device 200. Such control is performed with the stage position in the XY direction as an input. Thus, the control apparatus 100 moves the stage 230 to an operator's desired position. Here, the linear motor can be controlled using PID control or another commonly used servo control method.

The control apparatus 100 has a memory 130, a central processing unit (CPU) 140, and a storage device (storage unit) 150 such as a hard disk (HD). The control apparatus 100 further has an input device (input unit) 161 such as a keyboard and a mouse, a display device (display unit) 162 such as a display, and a communication device 163 such as a network card.

The storage device 150 stores overshoot amount data 151, a minimum stage stabilization range T0, beam shift amount data 152, and the like.

The overshoot amount data 151 stores an overshoot amount collected in the past and the like, and is used for estimating the overshoot amount caused by the stage movement.

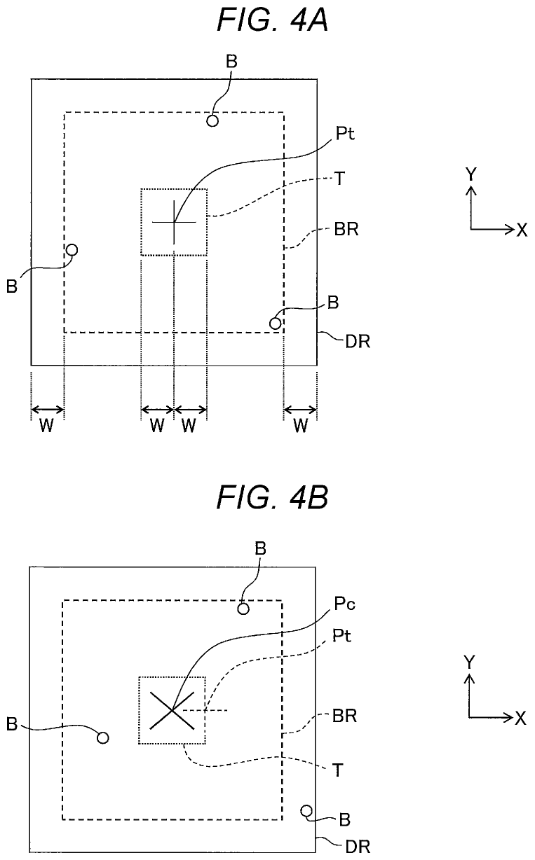

The minimum stage stabilization range T0 is a minimum value of a stage stabilization range T (see FIGS. 4A to 5) described later.

The beam shift amount data 152 is used when the setting of a permissible beam shift amount is automatically set as described later.

In the memory 130, a program stored in the storage device 150 is loaded. When executed by the CPU 140, the loaded program implements a processing unit 110, a permissible beam shift amount setting unit (maximum beam shift amount setting unit) 111 constituting the processing unit 110, an imaging range setting unit (permissible beam shift range setting unit) 112, a movement target position setting unit 113, a stage stabilization range setting unit 114, a stage movement amount calculation unit 115, an overshoot amount estimation unit 116, a movement target position correction unit 117, a stage movement control unit 118, an overshoot amount update unit 119, and an imaging control unit 120.

The permissible beam shift amount setting unit 111 sets a permissible beam shift amount (maximum value of the beam shift amount).

The imaging range setting unit 112 sets an imaging range to be described later.

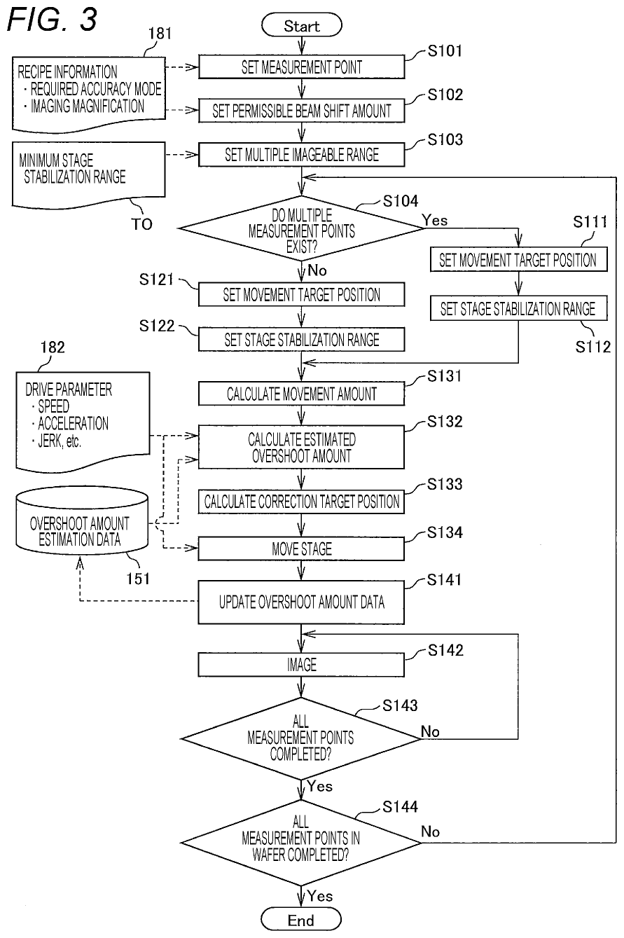

The movement target position setting unit 113 sets a measurement point B (see FIGS. 4A to 5) to be observed next based on the information read from recipe information 181 (see FIG. 3).

The stage stabilization range setting unit 114 performs setting of the stage stabilization range T (see FIGS. 4A to 5) described later.

The stage movement amount calculation unit 115 calculates the movement amount of the stage 230.

The overshoot amount estimation unit 116 estimates the overshoot amount accompanying the movement of the stage 230. The estimation of the overshoot amount is performed based on the movement amount of the stage 230 calculated by the stage movement amount calculation unit 115 and the overshoot amount data 151 stored in the storage device 150.

The movement target position correction unit 117 corrects the movement target position of the stage 230 based on the overshoot amount estimated by the overshoot amount estimation unit 116.

The stage movement control unit 118 moves the stage 230 toward the movement target position (correction target position) corrected by the movement target position correction unit 117. Specifically, the stage movement control unit 118 drives the X linear motor 223 and the Y linear motor 213 of the charged particle beam device 200. These drives are performed via the linear motor drive amplifier 171. Thus, the X stage 220 and the Y stage 210 (i.e., the stage 230) move. As will be described later in detail, when the stage position reaches within the stage stabilization range T, the stage movement control unit 118 changes the movement target position to any point within the stage stabilization range T.

The overshoot amount update unit 119 acquires an actual overshoot amount caused by the stage movement, and updates the overshoot amount data 151 using this overshoot amount.

The imaging control unit 120 controls imaging of the measurement point B on the wafer 202 by the charged particle beam device 200.

The above configuration enables the control apparatus 100 to move the wafer 202 in the XY plane with respect to the sample chamber 201 and to generate a secondary electron image by the column 251.

[Flowchart]

Next, an imaging procedure of the wafer 202 performed in the present embodiment will be described with reference to FIGS. 3 to 8.

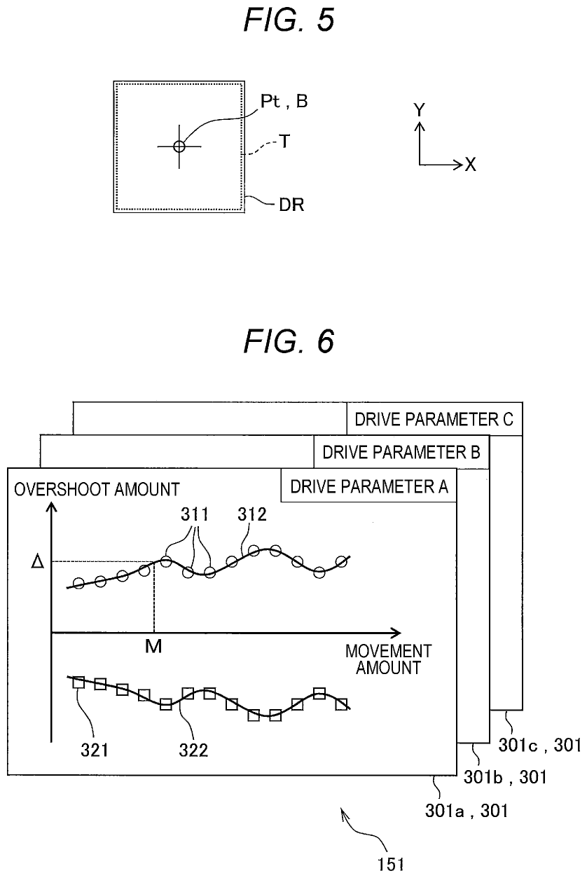

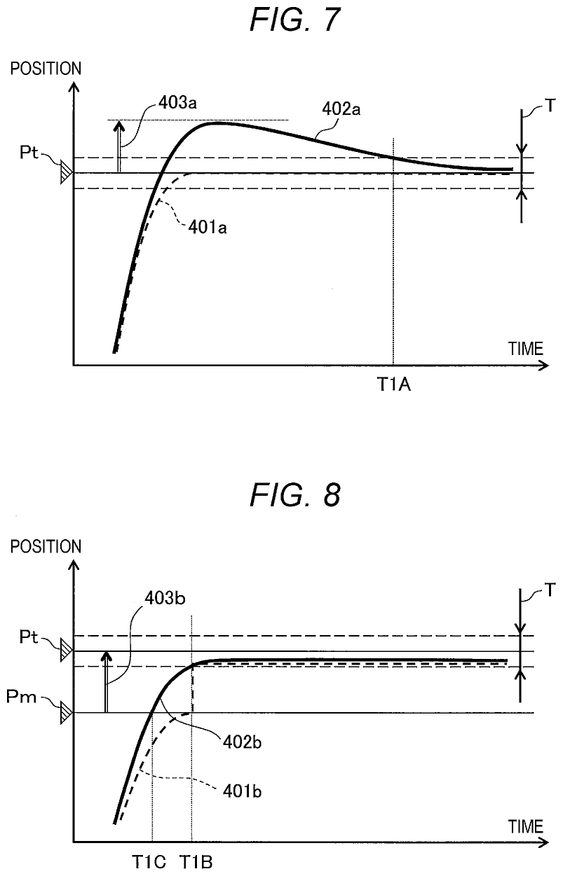

FIG. 3 is a flowchart presenting an imaging procedure of the wafer 202 executed in the present embodiment. FIGS. 4A to 5 are explanatory diagrams of the stage stabilization range T in the present embodiment. FIG. 6 is a view illustrating a calculation method of an estimated overshoot amount in the present embodiment. FIGS. 7 and 8 are views illustrating movement control of the stage 230. FIGS. 1 and 2 will be referred to as appropriate.

The processing of FIG. 3 is processing performed by the control apparatus 100.

First, when an operator executes a recipe via the input device 161 or the like, the plurality of measurement points B (see FIGS. 4A to 5) on the wafer 202 are set based on the recipe information 181 (S101).

Then, the permissible beam shift amount setting unit 111 sets a permissible beam shift amount (S102). The permissible beam shift amount is the maximum value of the beam shift amount used for correction of deviation of the stage position and field of view movement, and is set, for example, within ±10 μm. As illustrated in FIG. 3, the permissible beam shift amount is decided by the required accuracy mode and the imaging magnification that are included in the recipe information 181. The permissible beam shift amount can be the same for all the measurement points B on the wafer 202, or can be different for each measurement point B (see FIGS. 4A to 5).

Then, the imaging range setting unit 112 sets the imaging range using the permissible beam shift amount and the minimum stage stabilization range T0 (S103).

The minimum stage stabilization range T0 is the minimum value of the stage stabilization range T (see FIGS. 4A to 5). The stage stabilization range T is a permissible range for positioning such that all the measurement points B fall within the permissible beam shift amount even if a deviation occurs during positioning of the stage 230. The stage stabilization range T is described later with reference to FIGS. 4A to 5.

The minimum stage stabilization range T0 is set in advance, for example, is set within 0.1 μm. The stage stabilization range T will be described later.

In step S103, the imaging range setting unit 112 sets the imaging range at E=DR−T0. Here, E represents an imaging range, and DR represents a permissible beam shift range. The permissible beam shift range DR is the maximum range where the electron beam by the beam shift reaches. T0 represents the minimum stage stabilization range.

This imaging range will be described later with reference to FIG. 4A.

Next, the imaging range setting unit 112 determines whether or not the plurality of measurement points B exist in the imaging range (S104). In this processing, the imaging range setting unit 112 determines whether or not imaging of the plurality of measurement points B is possible after the next stage movement. Here, the order of the measurement points B on the wafer 202 is sometimes determined in advance, or sometimes only the coordinate of the measurement points B is determined and the order is not determined. As described above, in the present embodiment, since the structure of the wafer 202 to be measured is known by the design data or the like, it is possible to set the order of the measurement points B and the coordinate of the measurement points B in advance.

Here, if the order of the measurement points B is determined by the recipe information 181, the imaging range setting unit 112 sets the measurement points B that can be imaged in the imaging range.

If the order of the measurement points B is not determined by the recipe information 181, the imaging range setting unit 112 performs the following processing. That is, the imaging range setting unit 112 determines whether or not there is another measurement point B that can be imaged in the imaging range in the vicinity of the next measurement point B with respect to the unmeasured measurement point B on the wafer 202. When there is another measurement point B, the imaging range setting unit 112 decides the measurement order of the measurement points B in the imaging range. Here, the measurement order of the measurement points B is a so-called traveling salesman problem, and it may be decided by a known approximation algorithm or the like. Thus, the measurement point B to be measured next is set. The measurement order of the measurement points B is only required to be decided once in one imaging range.

As a result of step S104, if the plurality of measurement points B exist in the imaging range (Yes in step S104), the movement target position setting unit 113 decides a movement target position Pt (see FIGS. 4A to 5) in the next stage movement (step S111). Here, as illustrated in FIG. 4A, the movement target position Pt is preferably an intermediate value between the maximum value and the minimum value at each of the XY coordinate of the plurality of measurement points B to be measured in the next measurement. In other words, the movement target position Pt is preferable in the middle between the measurement points B. Thus, it is possible to minimize the beam shift amount when measuring each measurement point B in the imaging range.

Next, the stage stabilization range setting unit 114 sets the stage stabilization range T in the next stage movement (S112).

That is, as illustrated in FIG. 4A, the stage stabilization range setting unit 114 changes the stage stabilization range T from the minimum stage stabilization range T0.

In FIG. 4A, the movement target position Pt is set to be the center of a plurality of measurement points B. Then, the stage stabilization range setting unit 114 sets a measurement point distribution range BR. As illustrated in FIG. 4A, the measurement point distribution range BR is a range including all of the measurement points B in the imaging range. Thereafter, the stage stabilization range setting unit 114 calculates the width of the range obtained by subtracting the measurement point distribution range BR from the permissible beam shift range DR. The permissible beam shift range DR is the maximum range where the electron beam by the beam shift reaches as described above. Then, the stage stabilization range setting unit 114 sets, as the stage stabilization range T, a square range having a length of 2 W on one side centered on the movement target position Pt.

For example, if the permissible beam shift range DR is ±10 μm and the coordinates of the measurement point B are distributed in a range (measurement point distribution range BR) of ±6 μm from the movement target position Pt, the stage stabilization range T is a square having a value of ±4 μm on one side centered on the movement target position Pt. Here, since the coordinates of the measurement point B have different distributions in the XY direction, the stage stabilization range T can have different values from each other in the XY direction.

The stage stabilization range T will be described specifically.

FIG. 4B illustrates a case where the movement position of the stage 230 is deviated to the reference sign Pc. The movement target position Pt in FIG. 4B corresponds to the movement target position Pt in FIG. 4A. As illustrated in FIG. 4B, even if the movement position is deviated to the reference sign Pc, if the deviated position is within the stage stabilization range T, all the measurement points B fall within the permissible beam shift range DR. Thus, it is possible to maximize the deviation of the permissible stage position while ensuring the beam shift amount for the field of view movement.

The minimum stage stabilization range T0 used in step S103 is the minimum value of the stage stabilization range T. The imaging range set in step S103 corresponds to the measurement point distribution range BR in a case where the stage stabilization range T is the minimum stage stabilization range T0. However, the imaging range in step S103 is different from the measurement point distribution range BR, and is for determining whether or not the plurality of measurement points B exist in the imaging range that is a range with a slight allowance from the permissible beam shift range DR.

Although it is possible to set the minimum stage stabilization range T0 to 0, if this is done, there is a possibility that the position of the measurement point B becomes close to the permissible beam shift range DR (see FIGS. 4A to 5). Therefore, it is desirable that the minimum stage stabilization range T0 is not 0.

The description returns to FIG. 3.

After step S112, the processing unit 110 proceeds with the processing to step S131.

As a result of step S104, if only one measurement point B exists in the imaging range (No in step S104), the movement target position setting unit 113 sets the movement target position Pt in the next stage movement (step S121). Subsequently, the stage stabilization range setting unit 114 sets the stage stabilization range T (S122). Here, the imaging range setting unit 112 sets the movement target position Pt, which is the target position of stage movement, as the coordinate of the next measurement point B, and sets the stage stabilization range T so as to coincide with the permissible beam shift range DR. The next movement target position Pt is set based on the information of the measurement point B set in step S101.

The stage stabilization range T set in step S121 will be described with reference to FIG. 5.

As illustrated in FIG. 5, in step S121, the imaging range setting unit 112 sets the movement target position Pt of the stage 230 so as to coincide with the coordinate of the measurement point B. When imaging at only one point is performed after stage movement, it is not necessary to perform field of view movement between the imaging points by the beam shift, and hence the entire permissible beam shift range DR can be used for correction of the position deviation after stage movement. That is, the stage stabilization range T of the stage 230 is set to coincide with the permissible beam shift range DR. Note that FIG. 5 illustrates the stage stabilization range T and the permissible beam shift range DR in a slightly shifted state from each for making the figure easier to see.

As illustrated in FIG. 5, by setting the stage stabilization range T to coincide with the permissible beam shift range DR, the position deviation of the stage position is permitted up to the permissible beam shift range DR centered on the measurement point B.

The description returns to FIG. 3.

After step S122, the processing unit 110 proceeds with the processing to step S131.

In step S131, the stage movement amount calculation unit 115 calculates a necessary movement amount of the stage 230 from the movement target position Pt and the current coordinate of the stage 230. At this time, the stage movement amount calculation unit 115 also calculates the movement direction of the stage 230.

Subsequently, the overshoot amount estimation unit 116 calculates an estimated overshoot amount Δ (S132). Here, the estimated overshoot amount Δ is an amount by which the position response of the stage 230 is estimated in advance from the movement target position at the time of positioning of the stage 230. Based on a drive parameter 182, the overshoot amount estimation unit 116 calculates the estimated overshoot amount based on the estimation processing described later. The drive parameter 182 is at least one of the speed, acceleration, and jerk of the stage 230 set in the recipe information 181, for example. Parameters other than the speed, acceleration, and jerk of the stage 230 may be used as the drive parameter 182. The overshoot amount data 151 is used for estimation of the overshoot amount. The overshoot amount data 151 is generated based on an actual overshoot amount that has occurred in the past as described later. Since the overshoot amount data is generated based on the actual overshoot amount that has occurred in the past, the overshoot amount data 151 includes a tendency of machine difference and error for each charged particle beam device 200. Since the stage movement amount to the next movement target position Pt is different in each of XY directions, the estimated overshoot amount Δ has different values in each of XY directions.

An example of a calculation method of the estimated overshoot amount will be described with reference to FIG. 6.

FIG. 6 presents an example of the overshoot amount data 151. In the example of FIG. 6, the overshoot amount data 151 is illustrated in a graph format in which the horizontal axis represents the movement amount of the stage 230 and the vertical axis represents the overshoot amount. A plurality of measurement data 311 indicate the overshoot amount detected by the past positive stage movement. Using the measurement data 311, by performing an N-th order approximation by using a method such as the least squares method, a continuous overshoot amount estimation function 312 with respect to the stage movement amount is derived. As the degree N is increased, small changes can be responded, but since the amount of calculation increases, it is preferable to select an appropriate numerical value in accordance with the characteristics of the stage 230 (for example, degree N=5). Similarly, an overshoot amount estimation function 322 is obtained using measurement data 321 of the past overshoot amount detected by the stage movement in a negative direction.

As illustrated in FIG. 6, in the overshoot amount data 151, such overshoot amount estimation data 301 is stored for each drive parameter 182 (reference signs 301a to 301c).

Thus, by storing the overshoot amount estimation function 312 as an estimation parameter, the overshoot amount estimation unit 116 calculates the estimated overshoot amount Δ based on a movement amount M at the time of the stage movement, for example. Since the characteristics of the stage 230 are different in the XY directions, the overshoot amount estimation function 312 is desirably stored for each XY direction (FIG. 6 illustrates the overshoot amount estimation function 312 only in the X direction).

As described above, the overshoot amount of the stage 230 varies depending not only on the movement amount and movement direction of the stage 230 but also on the drive parameters 182 such as the speed, acceleration, and jerk, and the coordinate of the stage 230. The overshoot amount is likely to be affected by the structure of the stage 230, external air temperature, atmospheric pressure, and the like, and these characteristics generally have machine differences (variations) depending on each device within a range of mechanical and electrical tolerances.

In FIG. 6, the series of overshoot amount estimation data 301a to 301c are the overshoot amount estimation data 301 in a certain drive parameter 182 (“drive parameter A” to “drive parameter C”). On the other hand, a plurality of drive parameters 182 of the stage 230 are sometimes used in accordance with the measurement sequence in the wafer 202. In such a case, it is effective to use the plurality of overshoot amount estimation data 301 accordingly. For example, there is a case where the “drive parameter B” is used in a certain measurement and the “drive parameter C” is used in a subsequent measurement. In this case, it is preferable to use the overshoot amount estimation data 301b in the measurement using the “drive parameter B” and use the overshoot amount estimation data 301c in the measurement using the “drive parameter C”. It is also possible to set the overshoot amount estimation data 301 for each divided area on the wafer 202. Alternatively, the estimated overshoot amount between the areas can be changed continuously by interpolating the overshoot amount estimation data 301 at the boundary between the areas.

When the input recipe information 181 uses a drive parameter 182 that is not included in the overshoot amount data 151, the closest drive parameter 182 may be used.

The overshoot amount data 151 is, as described above, data collected in advance by an experiment or the like, but is also updated by the actual operation of the charged particle beam device 200 as described later.

The description returns to FIG. 3.

After step S132, the movement target position correction unit 117 calculates (step S133) a correction target position Pm (see FIG. 8) using the estimated overshoot amount Δ calculated in step S132. The correction target position Pm is a coordinate set as a target position at the time of start of stage movement, and is calculated by Pm=Pt−Δ.

Then, the stage movement control unit 118 performs stage movement with respect to the correction target position Pm (S134). Here, the stage movement control unit 118 generates a command trajectory 401b (see FIG. 8) using the drive parameter 182 with respect to the movement path from the current position to the correction target position Pm, and performs servo control so as to follow the command trajectory. Thus, the stage movement is performed.

The stage movement will now be described with reference to FIGS. 7 and 8. In FIGS. 7 and 8, the vertical axis indicates the movement position (position) of the stage 230, and the horizontal axis indicates time.

FIG. 7 is a view illustrating conventionally performed movement control of the stage.

In FIG. 7, the stage movement control unit 118 performs positioning within the range of the stage stabilization range T with respect to the movement target position Pt of the stage 230. At this time, the stage movement control unit 118 generates a command trajectory 401a with respect to the movement path from the movement start position to the movement target position Pt. The stage movement control unit 118 performs servo control of the stage 230 so as to follow the generated command trajectory 401a. As a result, a response 402a of the stage position becomes a trajectory as illustrated in FIG. 7. Here, the command trajectory 401a is generated by using a trajectory generation calculation in which the command position is a cubic function of time, for example.

Here, as illustrated in FIG. 7, in the response 402a, an overshoot amount 403a is generated with respect to the movement target position Pt. After the generation of the overshoot, the stage movement control unit 118 performs feedback control so that the difference between the response 402a and the command trajectory 401a becomes small. As a result, the stage 230 almost reaches the movement target position Pt.

The overshoot amount 403a increases a positioning time T1A until the response 402a falls within the range of the stage stabilization range T. As described above, by improving the control band of the servo control system, the overshoot amount 403a can be reduced, but the control band is often limited by the influence of the resonance of the structure in the stage 230. It is also possible to position the stage so as not to overshoot by adjusting the drive parameter 182 (e.g., reducing the acceleration). However, since the time required for the command trajectory 401a to reach the movement target position Pt increases, the positioning time is not shortened in many cases.

FIG. 8 is a view illustrating the stage movement control performed in the present embodiment.

In FIG. 8, as described above, the stage movement amount calculation unit 115 calculates a necessary movement amount from the movement target position Pt and the current coordinate of the stage 230 (step S131 in FIG. 3).

Furthermore, as described above, the overshoot amount estimation unit 116 calculates the estimated overshoot amount Δ from the drive parameters 182 such as a predetermined speed, acceleration, and jerk (step S132 in FIG. 3). As described above, the movement target position correction unit 117 calculates the correction target position Pm from the movement target position Pt and the estimated overshoot amount Δ (step S133 in FIG. 3).

As described above, the stage movement control unit 118 performs the stage movement with respect to the correction target position Pm (step S134 in FIG. 3). Specifically, the stage movement control unit 118 generates the command trajectory 401b from the current position with respect to the correction target position Pm as illustrated in FIG. 8. In the command trajectory 401b, the correction target position Pm is switched to coincide with the stage stabilization range T at a time T1B, and the reason for this will be described later.

The stage movement control unit 118 performs servo control so as to follow the generated command trajectory 401b. At this time, a response 402b is positioned after an overshoot 403b occurs with respect to the correction target position Pm. If the estimation of the estimated overshoot amount Δ is correct, the response 402b of the stage 230 approaches the command trajectory 401b (stage stabilization range T) after reaching the correction target position Pm. In a case where the stage 230 is positioned using the correction target position Pm, the position response of the stage 230 where the overshoot 403b occurs is stabilized near the movement target position Pt. Thus, the positioning accuracy of the stage 230 can be improved.

Here, the reason why the command trajectory 401b is switched from the correction target position Pm to coincide with the stage stabilization range T at the time T1B when the response 402b reaches the stage stabilization range T will be described. If the command trajectory 401b remains at the correction target position Pm even after the time T1B, the response 402b makes an attempt to follow the correction target position Pm by servo control. Therefore, at the time T1B when the response 402b reaches the stage stabilization range T, the command trajectory 401b is switched from the correction target position Pm to coincide with the stage stabilization range T. This is performed to prevent the response 402b from separating from the stage stabilization range T again. When detecting that the stage position has reached the stage stabilization range T, the stage movement control unit 118 changes the command trajectory 401b to the stage stabilization range T. Whether or not the stage position has reached the stage stabilization range T is determined based on the relative displacements of the stage 230 in the X direction and the Y direction by the X laser interferometer 241 and the Y laser interferometer.

If the estimation of the overshoot amount is deviated, it is conceivable a case where the response 402b does not reach the stage stabilization range T. Even in this case, for example, at a time point (time T1C) when the command trajectory 401b reaches the correction target position Pm, the command trajectory 401b is updated to the stage stabilization range T. This makes it possible to ensure that the response 402b falls within the stage stabilization range T. Whether or not the stage position has reached the correction target position Pm is also determined based on the relative displacements of the stage 230 in the X direction and Y direction by the X laser interferometer 241 and the Y laser interferometer.

At the time T1B, the command trajectory 401b is changed to not the movement target position Pt but the stage stabilization range T. This is because, if the command trajectory 401b is changed to the movement target position Pt, the degree of the change becomes large, and therefore, a fluctuation or the like occurs in the response 402b. Therefore, the command trajectory 401b is changed to the stage stabilization range T because imaging is possible and the change of the command trajectory 401b is minimized. At the time T1B, the command trajectory 401b may be changed to the movement target position Pt, or may be any point in the stage stabilization range T.

By performing the processing as illustrated in FIG. 8, it is possible to greatly shorten the positioning time T1B until the stage position falls within the range of the stage stabilization range T. Furthermore, at this time, since the stage position is near the movement target position Pt, which is the original position desired to position, it is possible to reduce the beam shift amount necessary for position correction after the stage movement.

As described above in FIG. 5, when there is one measurement point B in the imaging range, the stage stabilization range T is set to coincide with the permissible beam shift range DR. By doing this, it is possible to shorten the time during which the stage 230 enters the stage stabilization range T. That is, it is possible to greatly shorten the stabilization time in step S230.

The description returns to FIG. 3.

After step S134, the overshoot amount update unit 119 detects an overshoot amount that actually occurred in the stage movement, and updates the overshoot amount data 151 (step S141). Here, the overshoot amount is detected using the response deviation of the stage position with respect to the correction target position Pm, and is updated based on an update algorithm described later.

It is desirable to collect data on the overshoot amount before shipment of the charged particle beam device 200 with respect to stage movement conditions assumed in advance (such as a stage movement amount) and the drive parameter 182 (speed, acceleration, jerk, and the like). On the other hand, since the overshoot amount can be collected for each actual stage movement, the overshoot amount data 151 can be updated during operation of the charged particle beam device 200. Thus, during operation of the charged particle beam device 200, it is possible to collect data on the frequently used movement amount and the overshoot amount with respect to the coordinate. Thus, it is expected to improve the estimation accuracy of the overshoot with respect to the frequently used stage movement conditions.

Examples of the update algorithm of the overshoot amount data 151 include one described below. When a new overshoot amount Δnow is obtained by the stage movement, the overshoot amount update unit 119 calculates the new overshoot amount Δnew by calculating the following expression (1) using past data Δold.

Δnew=a×Δnow+(1−a)×Δold (1)

The overshoot amount update unit 119 updates the measurement data 311 and 321 of the overshoot amount of the corresponding drive parameters 182 in the overshoot amount data 151 illustrated in FIG. 6. Furthermore, the overshoot amount update unit 119 updates the overshoot amount estimation functions 312 and 322 illustrated in FIG. 6. Note that an expression other than the expression (1) may be used for the update expression of the overshoot amount.

This makes it possible to maintain the estimation accuracy of the overshoot amount even if the overshoot amount changes with time or the like. Here, a coefficient a in expression (1) is a parameter for determining how much weight to put to past data. A small coefficient a stabilizes the change in the estimated overshoot amount Δ. By setting the coefficient a to 0, it is possible to continue using the overshoot amount data 151 having already been set, without updating the overshoot amount data 151.

The description returns to FIG. 3.

In step S142 of FIG. 3, the imaging control unit 120 performs beam shift in accordance with the position of the measurement point B, and images an SEM image for inspection. Here, the beam shift amount includes both the deviation of the stage position after the stage movement and the field of view movement amount in accordance with the measurement point distribution range BR (see FIGS. 4A to 5) at the time of measuring a plurality of points. The setting of the stage stabilization range T of the present embodiment ensures that the sum is within the permissible beam shift range DR (see FIGS. 4A to 5) decided in step S102.

Thereafter, the processing unit 110 determines whether or not imaging of all the measurement points B in the permissible beam shift range DR has been completed (S143).

As a result of step S143, if the imaging of all the measurement points B in the permissible beam shift range DR has not been completed (No in step S143), the processing unit 110 returns the processing to step S142. Then, the processing unit 110 repeats imaging of the SEM image without stage movement (i.e., by beam shift).

As a result of step S143, if the imaging of all the measurement points B in the permissible beam shift range DR has been completed (Yes in step S143), the processing unit 110 determines whether or not the imaging of all the measurement points B in the wafer 202 has been completed (step S144).

As a result of step S144, if the imaging of all the measurement points B in the wafer 202 has not been completed (No in step S144), the processing unit 110 returns the processing to the step S104.

As a result of step S144, if the imaging of all the measurement points B in the wafer 202 has been completed (Yes in step S144), the processing unit 110 ends the processing.

[Measurement Order]

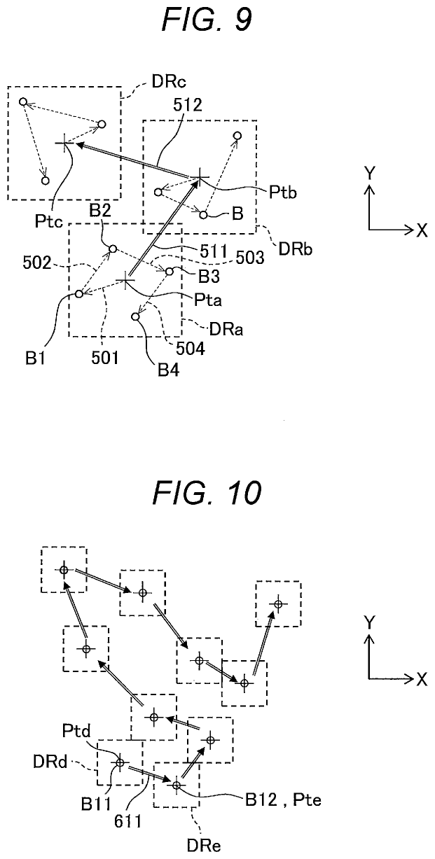

Next, the measurement order will be described with reference to FIGS. 9 and 10.

FIG. 9 is a schematic view illustrating the measurement order in a case of performing imaging of a plurality of points by one stage movement.

In the example of FIG. 9, first, the stage 230 is positioned in the vicinity of a movement target position Pta in a permissible beam shift range DRa, and the stage movement is performed so that the stage position becomes a movement target position Pta. Then, a measurement point B1 is imaged by performing field of view movement (reference sign 501) by the beam shift. Next, a measurement point B2 is imaged by performing field of view movement (reference sign 502) by the beam shift. Hereinafter, measurement points B3 and B4 are imaged by performing the beam shift similarly.

When all the measurement points B1 to B4 in the permissible beam shift range DRa are imaged, stage movement (reference sign 511) is performed, and the stage 230 moves to the vicinity of a next movement target position Ptb. All of the measurement points B in the permissible beam shift range DRb including the movement target position Ptb are imaged by the field of view movement by the beam shift. When all the measurement points B in the permissible beam shift range DRb are imaged, stage movement (reference sign 512) is performed, and the stage 230 moves to the vicinity of a next movement target position Ptc. Then, each of the measurement points B in the permissible beam shift range DRc including the movement target position Ptc is imaged by the field of view movement by the beam shift.

In each of the permissible beam shift ranges DRa to DRc, since the distribution of the measurement points B to be imaged is different, a stage stabilization range T having a different size is set.

FIG. 10 is a schematic view illustrating the measurement order in a case of performing imaging of one point for one stage movement.

The example of FIG. 10 illustrates a case where the permissible beam shift amount is set to be small, and it is an example where the stage movement is performed for each measurement point B every time. When a measurement point B11 is imaged, a movement target position Ptd is set to be the same as the coordinate of the measurement point B11. The stage stabilization range T is set to be the same as the permissible beam shift range DR. After the stage 230 is positioned in the vicinity of the movement target position Ptd in the permissible beam shift range DRd, the position deviation is corrected by the beam shift. Then, the measurement point B11 is imaged. Subsequently, stage movement (reference sign 611) is performed toward the vicinity of a measurement point B12 (movement target position Pte) of a permissible beam shift range DRe. Thereafter, similar stage movement and beam shift are sequentially performed, whereby imaging of each measurement point B is performed.

[Variations]

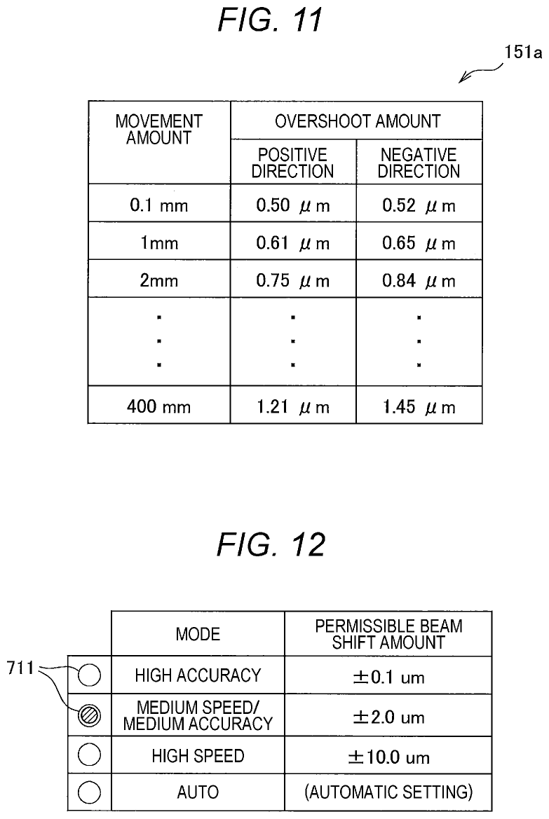

(Overshoot Amount Data 151a) FIG. 11 is a view illustrating a variation of overshoot amount data 151a in the present embodiment.

In FIG. 6, the movement amount and the overshoot amount are associated in the form of a graph. However, in FIG. 11, they are associated in the form of a table. In the case of the overshoot amount data 151a illustrated in FIG. 11, the overshoot amount estimation unit 116 refers in step S132 of FIG. 3 to the overshoot amount data 151a illustrated in FIG. 11 based on the movement amount calculated in step S131 and the movement direction of the stage 230. The overshoot amount estimation unit 116 calculates an estimated overshoot amount by selecting or interpolating an appropriate overshoot amount. The overshoot amount stored in the overshoot amount data 151a of FIG. 11 is a mean of the overshoot amounts actually detected in the past stage movement.

As described above, when the new overshoot amount Δnow is obtained by the actual stage movement, the new overshoot amount Δnew is preferably updated by expression (1) or the like using the past data Δold (see step S141 in FIG. 3). It is desirable that a plurality of tables illustrated in FIG. 11 are stored in the storage device 150 in accordance with the drive parameters 182, the coordinates, and the like, and the tables are selectively used in accordance with conditions.

The “positive direction” and the “negative direction” in FIG. 11 are the same as those in FIG. 6.

(Setting Example of Permissible Beam Shift Amount)

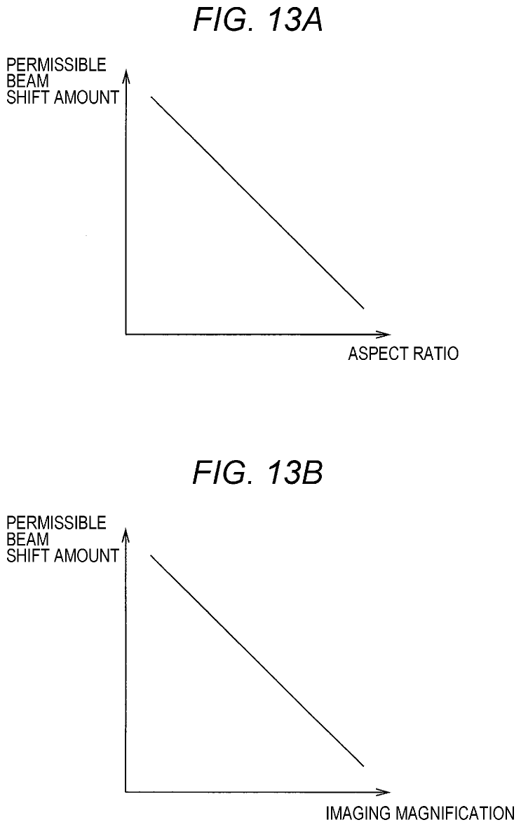

FIG. 12 is an example of a table for setting the permissible beam shift amount in the present embodiment. FIGS. 13A and 13B are views illustrating a setting map of the permissible beam shift amount in the auto mode.

The table presented in FIG. 12 is displayed on the display device 162 (see FIG. 2) in step S102 in FIG. 3, and is stored in the beam shift amount data 152 in FIG. 2.

In FIG. 12, a permissible beam shift amount is set for each of three modes of “high accuracy”, “medium speed/medium accuracy”, and “high speed”. In addition, a mode for automatically setting the permissible beam shift amount is also displayed as an auto mode. The operator selects one of these modes by selecting a radio button 711 via the input device 161. In the example of FIG. 12, the “medium speed/medium accuracy” mode is selected. This makes it possible to easily set the permissible beam shift amount. For example, the “high accuracy” mode is selected for measurement of a deep hole (aspect ratio: high) or measurement requiring accuracy at a high magnification, and the “high speed” mode is selected for measurement not requiring accuracy. Here, each mode can be set for the entirety of one wafer 202, but the mode can also be set individually for each measurement point B. In FIG. 12, the permissible beam shift amount is displayed on the screen as a numerical value, but the numerical value itself does not directly have a significant meaning, and hence it is also possible not to display the permissible beam shift amount.

In the “high accuracy” mode, the permissible beam shift amount becomes small, and it is hence desirable that one measurement point B is included in one permissible beam shift range DR as in FIG. 5 and FIG. 10. In the “high speed” mode, it is possible to include a plurality of measurement points B into one permissible beam shift range DR. In either case, the effects of the present embodiment described later can be achieved.

In FIG. 12, in the auto mode, the optimum permissible beam shift amount is calculated from the imaging magnification set by design data such as the dimension information of the measurement target pattern and the aspect ratio of the deep hole and the recipe information 181.

For example, as illustrated in FIG. 13A, a map presenting the aspect ratio on the horizontal axis and the permissible beam shift amount on the vertical axis is prepared in advance. The permissible beam shift amount setting unit 111 decides the permissible beam shift amount based on the aspect ratio of the hole measured under the auto mode. The aspect ratio of the hole to be measured can be easily calculated from the design data of the wafer 202 or the like.

As illustrated in FIG. 13B, a map presenting the imaging magnification on the horizontal axis and the permissible beam shift amount on the vertical axis is prepared in advance, and the permissible beam shift amount setting unit 111 decides the permissible beam shift amount based on the imaging magnification set under the auto mode.

Not that the permissible beam shift amount by the auto mode may be decided by a method other than that illustrated in FIGS. 13A and 13B.

The setting of the permissible beam shift amount by the auto mode is effective particularly in a case where there are many measurement points B and a plurality of types of measurements are performed on one wafer 202.

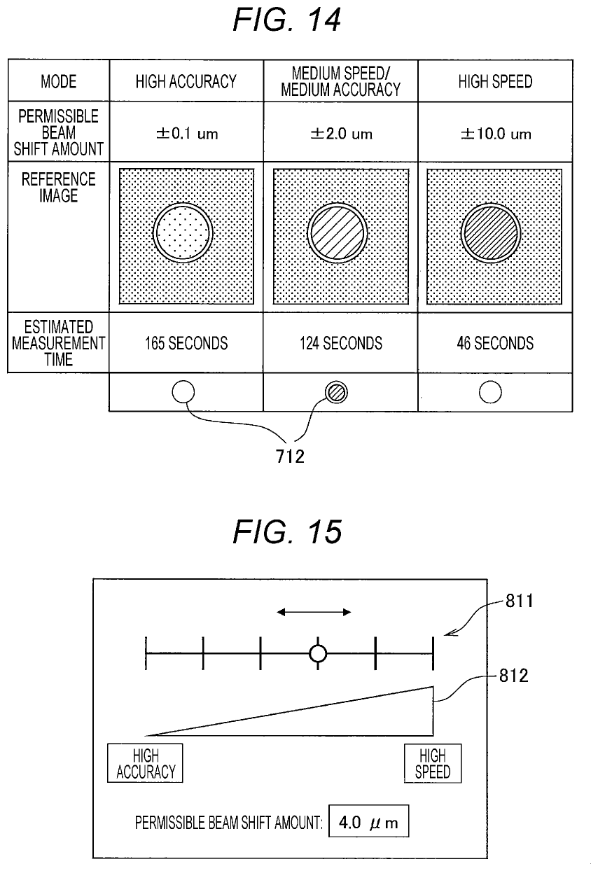

FIG. 14 is an example of a table for displaying a reference image with respect to the permissible beam shift amount in the present embodiment.

The table presented in FIG. 14 is displayed on the display device 162 (see FIG. 2) in step S102 in FIG. 3 similarly to FIG. 12. In the table presented in FIG. 14, a permissible beam shift amount is set for each of three modes of “high accuracy”, “medium speed/medium accuracy”, and “high speed”, and a reference image and an estimated measurement time are added thereto. Here, the reference image is assumed to be a hole having a concave structure, and is used to compare image deterioration and inspection sensitivity reduction in a case where the permissible beam shift amount increases. A part of the reference image that indicates the hole is bright in the “high accuracy” mode, dark in the “high speed” mode. The brightness in the “medium speed/medium accuracy” mode has an intermediate brightness between the “high accuracy” mode and the “high speed” mode. The operator selects one of these modes by selecting a radio button 712 via the input device 161. In the example of FIG. 14, the “medium speed/medium accuracy” mode is selected.

Display of such a reference image enables the operator to make a decision while confirming the affecting image deterioration when setting the mode. Here, the reference image to be displayed may be a previously obtained image, or an image in which the permissible beam shift amount is intentionally changed by using a semiconductor pattern that is an actual measurement object may be newly created and displayed. Alternatively, an image in which the permissible beam shift amount is changed based on the design data of the wafer 202 may be newly created and displayed. The estimated measurement time in FIG. 14 is a rough indication of the processing time of the entire wafer 202 estimated using the recipe information 181 as an index of high speed.

(Setting Example of Permissible Beam Shift Amount (Second Example))

FIG. 15 is a view explaining a decision method of the permissible beam shift amount in the present embodiment.

FIG. 15 is a screen displayed on the display device 162 in step S102 of FIG. 3.

The screen illustrated in FIG. 15 has a slide bar 811 capable of changing the imaging mode from the “high accuracy” to the “high speed”, and a display 812 indicating the permissible beam shift amount to be set. By operating the slide bar 811, the operator sets the necessary accuracy, and as a result, decides the permissible beam shift amount. Here, the slide bar 811 may be capable of setting the permissible beam shift amount discretely or continuously.

According to the present embodiment, it is possible to suppress the position deviation at the time of the stage movement due to overshoot. This makes it possible to shorten the stage movement time, and to reduce the permissible beam shift amount for correcting the deviation of the stage position. Along with this, it is possible to increase the beam shift amount used for field of view movement, and possible to enlarge the field of view movement by the beam shift. According to the present embodiment, the throughput can be improved by shortening of the stage movement time and enlargement of the field of view movement range by the beam shift.

Since the beam shift amount can be reduced, the beam tilt can be reduced. This makes it possible to improve the accuracy of an image imaged particularly in a deep hole or the like.

The present invention is not limited to the above-described embodiment, and includes various variations. For example, the above-described embodiment has been described in detail for the purpose of clearly explaining the present invention, and is not necessarily limited to one having all of the described configurations.

The above-described structures, functions, units 110 to 120, storage device 150, and the like may be implemented by hardware by designing some or all of them with an integrated circuit, for example. As illustrated in FIG. 2, each of the above-described structures, functions, and the like may be implemented by software by a processor such as the CPU 140 interpreting and executing a program that implements each function. Information such as a program, a table, and a file for implementing each function can be stored in a recording device such as the memory 130 and a solid state drive (SSD), or a recording medium such as an integrated circuit (IC) card, a secure digital (SD) card, and a digital versatile disc (DVD), other than being stored in a hard disk (HD).

In each embodiment, the control lines and the information lines that are considered to be necessary for explanation are illustrated, and not all the control lines and the information lines are necessarily illustrated on the product. In practice, almost all configurations may be considered to be interconnected.

### REFERENCE SIGNS LIST

100 control apparatus (stage movement control apparatus)
111 permissible beam shift amount setting unit (maximum beam shift amount setting unit)
112 imaging range setting unit (permissible beam shift range setting unit)
113 movement target position setting unit
114 stage stabilization range setting unit
115 stage movement amount calculation unit
116 overshoot amount estimation unit
117 movement target position correction unit
118 stage movement control unit
119 overshoot amount update unit
150 storage device (storage unit)
151 overshoot amount data
161 input device (input unit)
162 display device (display unit)
200 charged particle beam device
202 wafer (sample)
210 Y stage (stage)
213 Y linear motor (drive unit)
220 X stage (stage)
223 X linear motor (drive unit)
242 X mirror (position detection unit)
230 stage
241 X laser interferometer (position detection unit)
251 column
252 electron gun
253 deflector
BR measurement point distribution range
DR permissible beam shift range
T stage stabilization range

1. A stage movement control apparatus, comprising:
a storage unit that stores overshoot amount data in which a movement distance of a stage in a charged particle beam device and an overshoot amount of the stage are associated;
a movement target position setting unit that sets a movement target position of the stage;
a stage movement amount calculation unit that calculates a stage movement amount, which is an amount by which the stage moves in future toward the movement target position;
an overshoot estimation unit that estimates the overshoot amount corresponding to the stage movement amount based on the stage movement amount having been calculated and the overshoot amount data;
a movement target position correction unit that sets a correction movement target position in which the movement target position is corrected from the movement target position to a near side by the overshoot amount having been calculated; and
a stage movement control unit that moves the stage with respect to the correction movement target position.

2. The stage movement control apparatus according to claim 1, further comprising:
an overshoot amount update unit that updates overshoot amount data by acquiring the overshoot amount generated when the stage is actually moved by the stage movement control unit and reflecting the acquired overshoot amount on the overshoot amount data.

3. The stage movement control apparatus according to claim 1, further comprising:
a stage stabilization range setting unit that sets a stage stabilization range that is a permissible range of deviation of an arrival point, in which all measurement points exist in a range of beam shift of the charged particle beam device when the arrival point of the stage is deviated from the movement target position in movement of the stage.

4. The stage movement control apparatus according to claim 3, further comprising:
a maximum beam shift amount setting unit that sets a maximum value of a beam shift amount in the charged particle beam device; and
a permissible beam shift range setting unit that sets a permissible beam shift range that is a permissible range of the beam shift based on a maximum value of the beam shift amount,
wherein the stage stabilization range setting unit sets a measurement point distribution range that is a range including all measurement points existing in the permissible beam shift range, and sets, as the stage stabilization range, a region having a width of a range obtained by subtracting the measurement point distribution range from the permissible beam shift range with the movement target position as a center.

5. The stage movement control apparatus according to claim 3, further comprising:
a maximum beam shift amount setting unit that sets a maximum value of a beam shift amount in the charged particle beam device; and
a permissible beam shift range setting unit that sets a permissible beam shift range that is a permissible range of the beam shift based on a maximum value of the beam shift amount,
wherein the stage stabilization range setting unit designates the permissible beam shift range to be the stage stabilization range.

6. The stage movement control apparatus according to claim 3, wherein
the stage movement control unit
generates a command trajectory that is a trajectory for the stage is to move when performing movement of the stage, and performs movement of the stage based on the command trajectory,
generates the command trajectory toward the correction movement target position until the stage enters the stage stabilization range from a movement start point of the stage, and
changes the command trajectory when the stage enters the stage stabilization range so that an arrival point of the stage becomes any location in the stage stabilization range.

7. A charged particle beam system, comprising:
a charged particle beam device having an electron gun for generating a charged particle beam, a column equipped with a deflector capable of deflecting the charged particle beam generated from the electron gun to a desired position, a stage configured to be moveable in which a sample irradiated with the charged particle beam generated from the electron gun is placed, a drive unit that drives the stage, and a position detection unit that detects a position of the stage; and
a stage movement control apparatus that controls movement of the stage,
wherein the stage movement control apparatus includes
a storage unit that stores overshoot amount data in which a movement distance of the stage in the charged particle beam device and an overshoot amount of the stage are associated,
a movement target position setting unit that sets a movement target position of the stage,
a stage movement amount calculation unit that calculates a stage movement amount, which is an amount by which the stage moves in future toward the movement target position,
an overshoot estimation unit that estimates the overshoot amount corresponding to the stage movement amount based on the stage movement amount having been calculated and the overshoot amount data,
a movement target position correction unit that sets a correction movement target position in which the movement target position is corrected from the movement target position to a near side by the overshoot amount having been calculated, and
a stage movement control unit that moves the stage with respect to the correction movement target position.

8. The charged particle beam system according to claim 7, further comprising:
an overshoot amount update unit that updates overshoot amount data by acquiring the overshoot amount generated when the stage is actually moved by the stage movement control unit and reflecting the acquired overshoot amount on the overshoot amount data.

9. The charged particle beam system according to claim 7, further comprising:
a stage stabilization range setting unit that sets a stage stabilization range that is a permissible range of deviation of an arrival point, in which all measurement points exist in a range of beam shift of the charged particle beam device when the arrival point of the stage is deviated from the movement target position in movement of the stage.

10. The charged particle beam system according to claim 9, further comprising:
a maximum beam shift amount setting unit that sets a maximum value of a beam shift amount in the charged particle beam device; and
a permissible beam shift range setting unit that sets a permissible beam shift range that is a permissible range of the beam shift based on a maximum value of the beam shift amount,
wherein the stage stabilization range setting unit sets a measurement point distribution range that is a range including all measurement points existing in the permissible beam shift range, and sets, as the stage stabilization range, a region having a width of a range obtained by subtracting the measurement point distribution range from the permissible beam shift range with the movement target position as a center.

11. The charged particle beam system according to claim 9, further comprising:
a maximum beam shift amount setting unit that sets a maximum value of a beam shift amount in the charged particle beam device; and
a permissible beam shift range setting unit that sets a permissible beam shift range that is a permissible range of the beam shift based on a maximum value of the beam shift amount,
wherein the stage stabilization range setting unit designates the permissible beam shift range to be the stage stabilization range.

12. The charged particle beam system of claim 9, further comprising:
a maximum beam shift amount setting unit that sets a maximum value of a beam shift amount in the charged particle beam device,
wherein the maximum beam shift amount setting unit associates an imaging state of the charged particle beam device with a maximum value of the beam shift amount, and displays, on a display unit, a screen for selecting a maximum value of the beam shift amount via an input unit.

13. The charged particle beam system of claim 9, further comprising:
a maximum beam shift amount setting unit that sets a maximum value of a beam shift amount in the charged particle beam device,
wherein the maximum beam shift amount setting unit sets a maximum value of the beam shift amount based on at least one of a state of an imaging target and an imaging condition.

14. The charged particle beam system according to claim 9, wherein
the stage movement control unit
generates a command trajectory that is a trajectory for the stage is to move when performing movement of the stage, and performs movement of the stage based on the command trajectory,
generates the command trajectory toward the correction movement target position until the stage enters the stage stabilization range from a movement start point of the stage, and
changes the command trajectory when the stage enters the stage stabilization range so that an arrival point of the stage becomes any location in the stage stabilization range.

15. The charged particle beam system according to claim 7, wherein the overshoot amount data is stored for each drive parameter for moving the stage.
